(19) United States
(12) Patent Application Publication
(10) Pub. No.: US 2025/0216472 A1
(43) Pub. Date: Jul. 3, 2025

(54) BATTERY CELL HEALTH EVALUATION BASED ON STATE OF CHARGE DEVIATION

(71) Applicant: GM Global Technology Operations LLC, Detroit, MI (US)

(72) Inventors: Andrew C. Baughman, Northville, MI (US); Xiumei Guo, Troy, MI (US); Shubham Gupta, Ann Arbor, MI (US); Peyton Philip Huene, Novi, MI (US); Rajeev M. Ramanan, Northville, MI (US)

(21) Appl. No.: 18/403,202

(22) Filed: Jan. 3, 2024

(51) Int. Cl. G01R 31/392; B60L 58/12; B60L 58/16; G01R 31/3842; G01R 31/396

(52) U.S. Cl. CPC G01R 31/392; B60L 58/12; B60L 58/16; G01R 31/3842; G01R 31/396

(57) ABSTRACT

A system for evaluating a battery assembly includes a sensing device configured to acquire parameters related to a group of cells of the battery assembly, and a diagnostic module. The diagnostic module is configured to perform estimating a state of charge (SOC) value for the group of cells based on measurements performed during a selected time window, calculating a statistical value related to the estimated SOC value for the group of cells, assigning the estimated SOC value to a selected bin of a plurality of SOC bins based on the statistical value, each SOC bin of the plurality of SOC bins including a subset of a range of SOC values, calculating a deviation of each SOC value in the selected bin relative to a plurality of SOC values in the selected bin, and determining whether the group of cells is healthy based on the deviation.

### INTRODUCTION

The subject disclosure relates to batteries, and more specifically to estimations of battery parameters including state of charge.

Vehicles, including gasoline and diesel power vehicles, as well as electric and hybrid electric vehicles, feature battery storage for purposes such as powering electric motors, electronics and other vehicle subsystems. Battery system health monitoring is an important aspect of battery operation. Some monitoring methods involve determining state of charge (SOC) behavior within cells of a battery assembly.

### SUMMARY

In one exemplary embodiment, a system for evaluating a battery assembly includes a sensing device configured to acquire parameters related to a group of cells of the battery assembly, and a diagnostic module. The diagnostic module is configured to perform estimating a state of charge (SOC) value for the group of cells based on measurements performed during a selected time window, calculating a statistical value related to the estimated SOC value for the group of cells, assigning the estimated SOC value to a selected bin of a plurality of SOC bins based on the statistical value, each SOC bin of the plurality of SOC bins including a subset of a range of SOC values, calculating a deviation of each SOC value in the selected bin relative to a plurality of SOC values in the selected bin, and determining whether the group of cells is healthy based on the deviation.

In addition to one or more of the features described herein, the statistical value is an average group SOC calculated based on the measurements, and the deviation includes a group SOC deviation and a bin deviation, the group SOC deviation corresponding to a difference between the estimated SOC value and the average group SOC, the bin deviation corresponding to a difference between a SOC value in the selected bin and an average of the plurality of SOC values in the selected bin.

In addition to one or more of the features described herein, determining whether the group of cells is healthy includes calculating a change in the deviation.

In addition to one or more of the features described herein, the change in the deviation is based on a difference between the group SOC deviation and the bin deviation.

In addition to one or more of the features described herein, the group of cells is determined to be healthy based on the change in the deviation being less than a threshold change value.

In addition to one or more of the features described herein, each SOC value is acquired by calculating a voltage of the group of cells based on voltage samples taken during the selected time window, and estimating each SOC value based on an open circuit voltage (OCV)-SOC curve.

In addition to one or more of the features described herein, the diagnostic module is configured to accumulate cell balancing commands from a cell balancing process.

In addition to one or more of the features described herein, calculating the deviation includes compensating the change in the deviation based on the cell balancing commands.

In addition to one or more of the features described herein, the battery assembly is at least one of a battery module and a battery pack of a vehicle.

In another exemplary embodiment, a method of evaluating a battery assembly includes monitoring a group of cells of the battery assembly, estimating a state of charge (SOC) value for the group of cells based on measurements performed during a selected time window, calculating a statistical value related to the estimated SOC value for the group of cells, assigning the estimated SOC value to a selected bin of a plurality of SOC bins based on the statistical value, each SOC bin of the plurality of SOC bins including a subset of a range of SOC values, calculating a deviation of each SOC value in the selected bin relative to a plurality of SOC values in the selected bin, and determining whether the group of cells is healthy based on the deviation.

In addition to one or more of the features described herein, the statistical value is an average group SOC calculated based on the measurements, and the deviation includes a group SOC deviation and a bin deviation, the group SOC deviation corresponding to a difference between the estimated SOC value and the average group SOC, the bin deviation corresponding to a difference between a SOC value in the selected bin and an average of the plurality of SOC values in the selected bin.

In addition to one or more of the features described herein, determining whether the group of cells is healthy includes calculating a change in the deviation.

In addition to one or more of the features described herein, the change in the deviation is based on a difference between the group SOC deviation and the bin deviation.

In addition to one or more of the features described herein, the group of cells is determined to be healthy based on the change in the deviation being less than a threshold change value.

In addition to one or more of the features described herein, calculating the deviation includes compensating the deviation based on cell balancing commands accumulated from a cell balancing process.

In addition to one or more of the features described herein, the battery assembly is at least one of a battery module and a battery pack of a vehicle.

In yet another exemplary embodiment, a vehicle system includes a memory having computer readable instructions, and a processing device for executing the computer readable instructions, the computer readable instructions controlling the processing device to perform a method. The method includes monitoring a group of cells of a battery assembly, estimating a state of charge (SOC) value for the group of cells based on measurements performed during a selected time window, calculating a statistical value related to the estimated SOC value for the group of cells, assigning the estimated SOC value to a selected bin of a plurality of SOC bins based on the statistical value, each SOC bin of the plurality of SOC bins including a subset of a range of SOC values, calculating a deviation of each SOC value in the selected bin relative to a plurality of SOC values in the selected bin, and determining whether the group of cells is healthy based on the deviation.

In addition to one or more of the features described herein, the statistical value is an average group SOC calculated based on the measurements, and the deviation includes a group SOC deviation and a bin deviation, the group SOC deviation corresponding to a difference between the estimated SOC value and the average group SOC, the bin deviation corresponding to a difference between a SOC value in the selected bin and an average of the plurality of SOC values in the selected bin.

In addition to one or more of the features described herein, determining whether the group of cells is healthy includes calculating a change in the deviation based on a difference between the group SOC deviation and the bin deviation.

In addition to one or more of the features described herein, calculating the deviation includes compensating the deviation based on cell balancing commands accumulated from a cell balancing process.

The above features and advantages, and other features and advantages of the disclosure are readily apparent from the following detailed description when taken in connection with the accompanying drawings.

### BRIEF DESCRIPTION OF THE DRAWINGS

Other features, advantages and details appear, by way of example only, in the following detailed description, the detailed description referring to the drawings in which:

FIG. 1 is a top view of a motor vehicle including a battery assembly, in accordance with an exemplary embodiment;

FIG. 2 depicts an example of a range of state of charge (SOC), and a set of SOC bins selected according to an exemplary embodiment of a method of evaluating a battery cell group and/or battery assembly;

FIG. 3 is a flow diagram depicting aspects of a method of evaluating the health of a battery cell group and/or battery assembly, in accordance with an exemplary embodiment; and

FIG. 4 depicts a computer system in accordance with an exemplary embodiment.

### DETAILED DESCRIPTION

Devices, systems and methods are provided for assessing the health of a battery cell group and/or a battery assembly. An embodiment of a battery health evaluation system is configured to determine battery health based on state of charge (SOC) information collected over time. The system divides a selected SOC range into a plurality of subsets or bins, and accumulates SOC estimations of battery cell groups over a selected time window.

For each cell group in a battery module (or each cell group in another battery assembly or battery system), an SOC value is estimated and an average SOC is calculated based on measurements (e.g., voltage samples) for each cell group and/or the battery module. For each cell group, the estimated SOC value is assigned to a respective bin based on the average SOC. If there are previously acquired SOC values in the bin for that module, an average of the SOC values in the bin (a “bin average”) is calculated.

A difference between the estimated SOC value and the average SOC (referred to as a “first deviation” or “group SOC deviation”) is calculated. A difference between each of the SOC values in the bin and the bin average (referred to as a “second deviation” or “bin deviation”) is determined. For example, a battery cell group is determined to be faulty if a change in the first deviation over time is above a threshold value. In an embodiment, a battery cell group is determined to be faulty if a difference between the first deviation and the second deviation is above a threshold difference value.

Embodiments described herein present numerous advantages and technical effects. The embodiments provide for effective diagnosis of battery health via monitoring changes in SOC, providing improved robustness of a battery assembly over the assembly lifetime. The embodiments also reduce the impact of capacity variations by grouping SOC values into bins as described herein, allowing for accurate diagnostic processes over a large SOC range.

The embodiments are not limited to use with any specific vehicle and may be applicable to various contexts. For example, embodiments may be used with automobiles, trucks, aircraft, construction equipment, farm equipment, automated factory equipment and/or any other device or system that utilizes rechargeable energy storage systems.

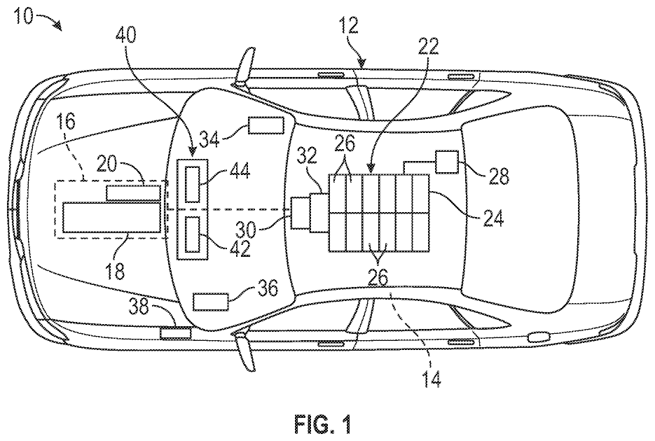

FIG. 1 shows an embodiment of a motor vehicle 10, which includes a vehicle body 12 defining, at least in part, an occupant compartment 14. The vehicle body 12 also supports various vehicle subsystems including a propulsion system 16, and other subsystems to support functions of the propulsion system 16 and other vehicle components, such as a braking subsystem, a suspension system, a steering subsystem, a fuel injection subsystem, an exhaust subsystem and others.

The vehicle 10 may be a combustion engine vehicle, an electrically powered vehicle (EV) or a hybrid vehicle. In an embodiment, the vehicle 10 is a hybrid vehicle that includes a combustion engine system 18 and at least one electric motor assembly. In an embodiment, the propulsion system 16 includes an electric motor 20, and may include one or more additional motors positioned at various locations. The vehicle 10 may be a fully electric vehicle having one or more electric motors.

The vehicle 10 includes a battery system 22, which may be electrically connected to the motor 20 and/or other components, such as vehicle electronics. The battery system 22 may be configured as a rechargeable energy storage system (RESS). In an embodiment, the battery system 22 includes a battery assembly such as a high voltage battery pack 24 having a plurality of battery modules 26. The battery system 22 may also include a monitoring unit 28 that includes components such as a processor, memory, an interface, a bus and/or other suitable components.

A “battery assembly,” in an embodiment, refers to a group of battery cells (i.e., two or more cells). For example, the battery assembly may be the battery pack 24, a battery module 26 or a group of cells (not shown) in a module 26.

Each battery module includes a plurality of cells (not shown) having a selected chemistry. In an embodiment, each cell is a lithium-ion battery, such as a lithium ferro-phosphate (LFP) battery or lithium nickel manganese colbalt oxide (NCM) battery. The battery pack 24 is not so limited and can have any suitable chemistry. Other examples include nickel-metal hydride and lead acid chemistries.

The battery assembly includes one or more groups of cells (“cell groups”). A cell group, in an embodiment, is a battery module 26 or a group of cells within the battery module 26.

The battery system 22 is electrically connected to components of the propulsion system 16. The propulsion system also includes an inverter module 30 and a direct current (DC)-DC converter module 32. The inverter module 30 (e.g., a traction power inverter unit or TPIM) converts DC power from the battery system 22 to poly-phase alternating current (AC) power (e.g., three-phase, six-phase, etc.) to drive the motor 20.

Various control modules (electronic control modules or ECUs) may be included in the vehicle 10. For example, an auxiliary power module (APM) 34 is included for providing power to accessories (e.g., 12V loads). An on-board charger module (OBCM) 36 may be included, which connects the battery system 22 to a charge port 38, and controls aspects of charging the battery system 22 (e.g., from a charging station, grid or other vehicle) and/or providing charge to an external system.

The vehicle 10 also includes a computer system 40 that includes one or more processing devices 42 and a user interface 44. The various processing devices and units may communicate with one another via a communication device or system, such as a controller area network (CAN) or transmission control protocol (TCP) bus.

One or more processing devices are configured to monitor and evaluate battery health, and identify one or more fault conditions. An embodiment of an evaluation system includes a processing device, such as a processing device in the vehicle (e.g., the OBCM 36, the monitoring unit 28 and/or an RESS controller), that acquires or estimates state of charge (SOC) values over time. An SOC range is selected, and the range is divided into a plurality of subsets or bins.

An SOC value for a cell group (e.g., a module 26) may be estimated by collecting voltage measurements or samples over time, estimating a group voltage, and determining an SOC value for the cell group. Upon estimating a cell group's SOC value for a selected time window, an average group SOC (or other statistical value) is calculated using the measurements. The estimated SOC value is assigned to a bin based on the average group SOC.

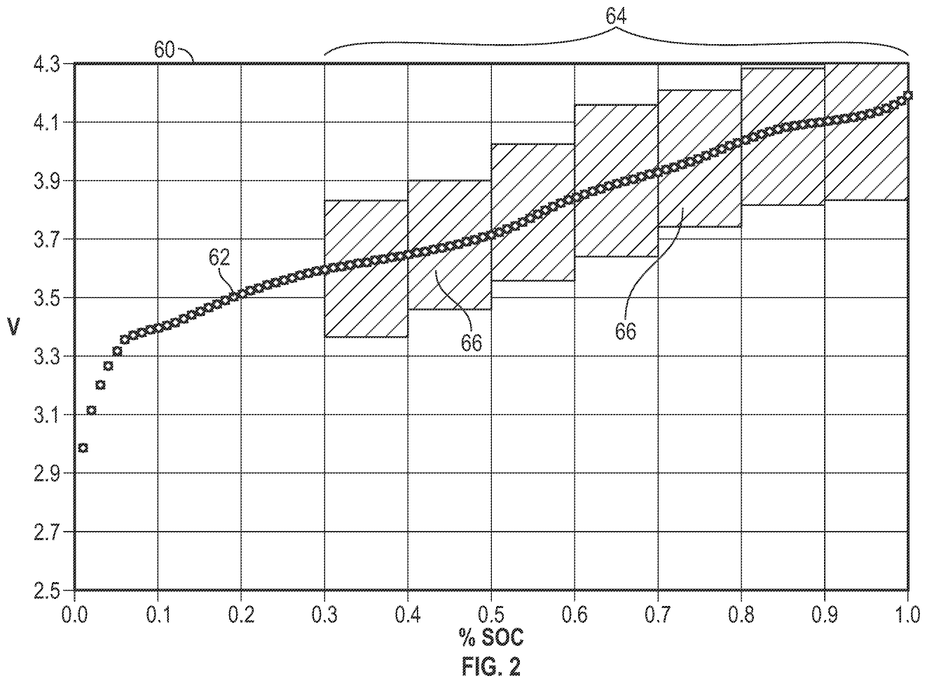

FIG. 2 depicts an example of a SOC range and division of the SOC range into SOC bins. In this example, SOC values are based on associated open circuit voltage (OCV) values. Correlations between SOC and OCV may be determined via modelling and/or experimentally.

FIG. 2 shows a graph 60 of OCV (in volts (V)) as a function of SOC, which is expressed as a percentage of cell capacity. An OCV-SOC curve 62 shows OCV as a function of SOC for a group of battery cells. In this example, an SOC range 64 is selected as a range between 30% and 100% of capacity, and the SOC range 64 is divided into a plurality of subsets, referred to as bins 66.

Embodiments are described herein with reference to the graph 60 and the bins 66 of FIG. 2 for illustration purposes. The embodiments are not limited to any specific OCV-SOC curve, voltage range or bin selection.

The health of a cell group, in an embodiment, is evaluated based on comparing each SOC value in a bin 66 to other SOC values in the bin 66. Each SOC value in the bin 66 (or only the estimated SOC value) is compared to a statistical value related to the data in the bin 66. In an embodiment, the statistical value is an average of the SOC values in the bin (“bin average”). The health of a group of battery cells may be determined based on a deviation of a SOC value in the bin 66 from the bin average (or other statistical value). This deviation is referred to as a “bin deviation.”

In an embodiment, the health of the group of battery cells is determined by comparing the bin deviation to previous deviations (e.g., bin deviations calculated in previous iterations). A change or trend in the bin deviation relative to previous bin deviations is calculated and used to determine the health. For example, the group of cells is determined to be healthy if the change in the bin deviation is below a selected threshold change value.

In an embodiment, the health of the group of battery cells is determined by comparing the bin deviation to a deviation related to SOC values estimated from measurements (“group SOC deviation”). The group SOC deviation is determined by estimating a group voltage and corresponding SOC value based on a set of measurements (e.g., voltage samples), and calculating an average SOC from the set of measurements. The group SOC deviation is a difference between the estimated SOC value and the average group SOC. The group of cells is determined to be healthy if a difference between the bin deviation and the group SOC deviation is below a selected threshold value.

In an embodiment, the one or more processing devices acquire cell balancing information related to cell balancing operations performed during a time window. For example, cell balancing commands, that prescribe the charging or discharging of cells within a battery assembly (in order to balance the SOC among the cells), are used to determine any charging or discharging that occurred due to cell balancing. The cell balancing commands may be used to compensate deviation calculations.

Cell balancing processes are used to equalize the SOC among the cells in a battery assembly, such as the battery module 26 or the battery pack 24. Cell balancing can minimize cell-to-cell performance variations and can mitigate the impact of cell degradation in individual cells. In some embodiments, cell balancing involves redistributing energy and/or charge between cells in a battery pack to achieve a more uniform SOC.

A balancing process includes estimating or measuring a state of charge (SOC) of each cell group in a battery assembly. A cell group may be a module 26, or a group of connected cells within a module. The cell group having the lowest state of charge is identified, and the identified SOC is compared to the SOC of each other power cell group. If a cell group exceeds the identified SOC by a selected threshold amount (i.e., is out of balance), energy from the out of balance cell group is discharged until the out of balance cell(s) fall within the threshold amount.

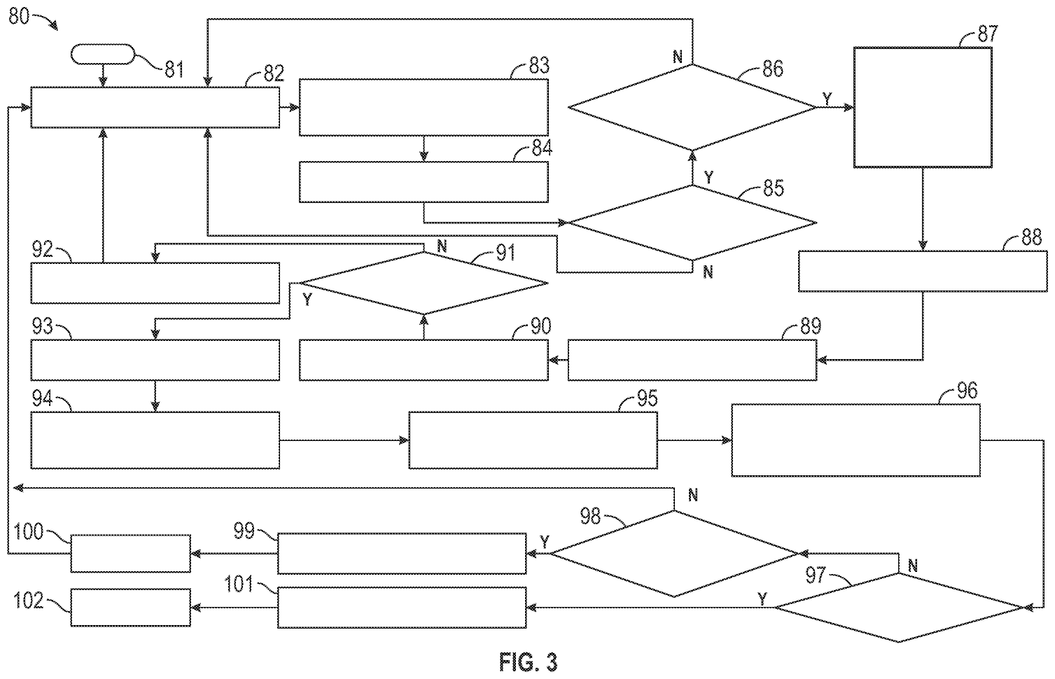

FIG. 3 illustrates embodiments of a method 80 of evaluating a battery assembly (e.g., the battery pack 24). Aspects of the method 80 may be performed by a processor or processors disposed in the vehicle 10 (e.g., the monitoring unit 28, the computer system 40, etc.). It is noted that the method 80 is not so limited and may be performed by any suitable processing device or system, or combination of processing devices. In addition, the method 80 is not limited to use with the vehicle 10, as the method 80 may be performed in conjunction with any suitable battery or battery system.

The method 80 includes a number of steps or stages represented by blocks 81-102. The method 80 is not limited to the number or order of steps therein, as some steps represented by blocks 81-102 may be performed in a different order than that described below, or fewer than all of the steps may be performed.

At block 81, a processing device monitors the battery system 22. For example, measurements of voltage, current and/or other parameters are performed at a plurality of measurement times or sample times. An SOC range is selected and the SOC range is divided into a plurality of successive bins. The bins may be of equal length, such as the bins of FIG. 2, but are not so limited.

At block 82, a time window for collecting measurements is selected, referred to as a filter length. In addition, a range of voltages is selected (filter voltages), and an OCV-SOC curve is acquired for each cell group (e.g., each module 26) to be evaluated. Measurement data is collected over time by collecting voltage samples during the time window. It is noted that sample collection continues at the end of the time window, such that measurement data is collected and a group voltage, SOC value and an average SOC can be determined for each successive time window.

The time window may be any period of operation of the vehicle 10. For example, the time window may encompass one or more periods in which the battery pack 24 is discharging (e.g., when the vehicle 10 is under propulsion). In addition, or alternatively, the time window may encompass periods when the battery pack is being charged via the charge port 38.

At block 83, cell balancing information is acquired. In an embodiment, cell balancing commands generated via a cell balancing process are collected and accumulated during battery operation and/or charging. The cell balancing information is acquired by accessing accumulated cell balancing commands. For each cell balancing command, the Amp-hours (Ah) that are dissipated from each cell group are calculated. The dissipated Amp-hours determined from balancing commands are accumulated over a time period between the last bin update (see block 92) and the current cell balancing calculation.

In an example, cell balancing command impact is determined by accumulating cell balancing commands (e.g., summing the dissipated Amp-hours associated with each command). The cell balancing commands may be accumulated prior to the onset of the method 80 (or after determination that a cell group is healthy or unhealthy) and continue to be accumulated until the conditions of blocks 85 and 87 are satisfied.

At block 84, the polarization voltage is estimated, and the processing device determines whether various conditions are met.

At block 85, the processing device determines whether a filter condition is met. The filter condition is used to determine whether there is sufficient data for an evaluation. For example, the processing device determines several voltage samples collected over the filter length. If the number of collected samples is below a threshold, there is insufficient date for estimating the group voltage (i.e. the filter condition is not met), and the processing device continues to accumulate data at block 82.

At block 86, the polarization voltage is compared to a selected threshold. If the polarization voltage is above the threshold, the method returns to block 82.

At block 87, for each cell group (e.g., module 26) being measured, an SOC value is calculated based on the collected voltage samples. In an embodiment, the SOC value is calculated for a cell group based on an OCV-SOC curve associated with the cell group.

For example, if there are sufficient voltage samples and the polarization condition is met, the cell group voltage is determined from the collected voltage samples, and is used to determine a filtered SOC value. The cell group voltage is fed to the OCV-SOC curve to produce a filtered SOC value. For example, the group voltage can be filtered and then fed to the OCV curve to get the filtered SOC value, or the raw group voltage can be fed to the OCV-SOC curve and subsequently filtered to obtain the filtered SOC value.

At block 88, an average of the SOC values in the bin is calculated (bin average). The method 80 can be changed to include other statistical characteristics of the data in a bin. Thus, the filtered SOC value in a bin can be compared with any preferred statistical characteristic.

At block 89, a bin deviation is calculated for the filtered SOC and the relevant bin data. In an embodiment, the bin deviation corresponds to a difference between the filtered SOC value in the bin and the bin average. In addition, an average SOC is calculated based on measurements acquired during the present time window, and a group SOC deviation is calculated as the difference between the calculated SOC value for the cell group and the average SOC.

At block 90, the bin is evaluated based on the filtered average SOC. For example, at block 91, each bin is inspected and it is determined whether there is data in the bin, for example, from previous SOC estimations. If not, the method proceeds to block 92, where the bin is updated, and a filter used for collecting voltage samples is reset.

At block 93, for each bin that has data, cell balancing information is used to calculate an amount of discharge that has occurred in the cell group due to cell balancing. For example, the average amp-hours that was balanced for the group of cells relative to the average SOC is calculated based on a cell balancing command (e.g., based on the commanded amount of energy dissipation). The average Amp-hours for each of a plurality of cell balancing commands are accumulated, for example, over a time period from a time when the bin was last updated and the group voltage calculated in a current iteration of the method 80.

The amp-hours accumulated between the current filtered SOC and a previous filtered SOC may be determined by an open-loop calculation using estimations of cell group voltage and balance resistance.

At block 94, a deviation is compensated using cell balancing information. For example, cell balancing commands are used to identify cells that were discharged for balancing purposes. If a cell group was balanced, the amount of charge that was discharged is subtracted from the observed trend in the deviation associated with that cell group. Cell balancing may be used to compensate the bin deviation and/or the group SOC deviation.

At block 95, a change in the deviation is calculated. The change in the deviation may be a difference between a current bin deviation and a previously bin deviation. The change in the deviation may be a difference between the bin deviation and the group SOC deviation.

At block 96, a threshold is selected or calculated. The threshold is an amount of change of the deviation.

In an embodiment, the threshold is a dynamic threshold that is calculated using the current average SOC.

The dynamic threshold is a function of total time between filtered SOC estimations (i.e., the time elapsed from when a previous filtered SOC was calculated in a previous iteration of the method 80, to when the current filtered SOC was estimated). The dynamic threshold is also a function of a static offset, and the difference in the average SOC between the filtered SOC estimations.

In an embodiment, the threshold is equal to the maximum of the elapsed time, a first growth factor, and “squelch”. Squelch grows with error sources and is module-specific. Squelch can be calculated as follows:

Squelch=a static offset+(absolute value of the difference in the

average group SOC between the present and a previous iteration)*GF2+(time

between the present and previous iteration)*GF3,

where GF2 is a second growth factor and GF3 is a third growth factor.

At block 97, the change in the deviation is compared to the threshold (e.g., a dynamic threshold or a static threshold). If the change in the deviation exceeds the threshold for any of the SOC values in the selected bin, the bin is updated at block 101, and a fault or failure indication is output at block 102. The indication may be provided to another processing device or system, or displayed to a user. The failure indication may be in any suitable format and provide information in any manner suitable to convey that the change in deviation is too high and a high-discharge condition is present.

At block 98, if none of the deviation changes exceed the threshold, the processing device determines that the cells for the bin are healthy (or at least pass this diagnostic method). At block 99, the bin is updated, and an indication that the cells for the selected bin are healthy (block 100).

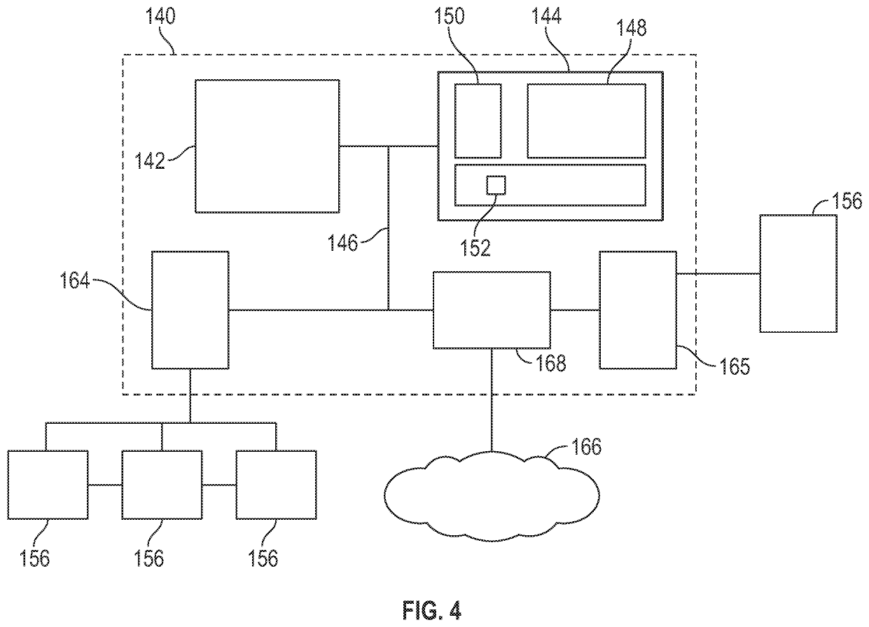

FIG. 4 illustrates aspects of an embodiment of a computer system 140 that can perform various aspects of embodiments described herein. The computer system 140 includes at least one processing device 142, which generally includes one or more processors for performing aspects of image acquisition and analysis methods described herein.

Components of the computer system 140 include the processing device 142 (such as one or more processors or processing units), a memory 144, and a bus 146 that couples various system components including the system memory 144 to the processing device 142. The system memory 144 can be a non-transitory computer-readable medium, and may include a variety of computer system readable media. Such media can be any available media that is accessible by the processing device 142, and includes both volatile and non-volatile media, and removable and non-removable media.

For example, the system memory 144 includes a non-volatile memory 148 such as a hard drive, and may also include a volatile memory 150, such as random access memory (RAM) and/or cache memory. The computer system 140 can further include other removable/non-removable, volatile/non-volatile computer system storage media.

The system memory 144 can include at least one program product having a set (e.g., at least one) of program modules that are configured to carry out functions of the embodiments described herein. For example, the system memory 144 stores various program modules that generally carry out the functions and/or methodologies of embodiments described herein. A module or modules 152 may be included to perform functions related to acquiring OCV, SOC and other battery assembly measurements, and battery health evaluation as discussed herein. The system 140 is not so limited, as other modules may be included. As used herein, the term “module” refers to processing circuitry that may include an application specific integrated circuit (ASIC), an electronic circuit, a processor (shared, dedicated, or group) and memory that executes one or more software or firmware programs, a combinational logic circuit, and/or other suitable components that provide the described functionality.

The processing device 142 can also communicate with one or more external devices 156 as a keyboard, a pointing device, and/or any devices (e.g., network card, modem, etc.) that enable the processing device 142 to communicate with one or more other computing devices. Communication with various devices can occur via Input/Output (I/O) interfaces 164 and 165.

The processing device 142 may also communicate with one or more networks 166 such as a local area network (LAN), a general wide area network (WAN), a bus network and/or a public network (e.g., the Internet) via a network adapter 168. It should be understood that although not shown, other hardware and/or software components may be used in conjunction with the computer system 140. Examples include, but are not limited to: microcode, device drivers, redundant processing units, external disk drive arrays, RAID systems, and data archival storage systems, etc.

The terms “a” and “an” do not denote a limitation of quantity, but rather denote the presence of at least one of the referenced item. The term “or” means “and/or” unless clearly indicated otherwise by context. Reference throughout the specification to “an aspect”, means that a particular element (e.g., feature, structure, step, or characteristic) described in connection with the aspect is included in at least one aspect described herein, and may or may not be present in other aspects. In addition, it is to be understood that the described elements may be combined in any suitable manner in the various aspects.

When an element such as a layer, film, region, or substrate is referred to as being “on” another element, it can be directly on the other element or intervening elements may also be present. In contrast, when an element is referred to as being “directly on” another element, there are no intervening elements present.

Unless specified to the contrary herein, all test standards are the most recent standard in effect as of the filing date of this application, or, if priority is claimed, the filing date of the earliest priority application in which the test standard appears.

Unless defined otherwise, technical and scientific terms used herein have the same meaning as is commonly understood by one of skill in the art to which this disclosure belongs.

While the above disclosure has been described with reference to exemplary embodiments, it will be understood by those skilled in the art that various changes may be made and equivalents may be substituted for elements thereof without departing from its scope. In addition, many modifications may be made to adapt a particular situation or material to the teachings of the disclosure without departing from the essential scope thereof. Therefore, it is intended that the present disclosure not be limited to the particular embodiments disclosed, but will include all embodiments falling within the scope thereof.

What is claimed is:

1. A system for evaluating a battery assembly, comprising:
a sensing device configured to acquire parameters related to a group of cells of the battery assembly; and
a diagnostic module configured to perform:
estimating a state of charge (SOC) value for the group of cells based on measurements performed during a selected time window;
calculating a statistical value related to the estimated SOC value for the group of cells;
assigning the estimated SOC value to a selected bin of a plurality of SOC bins based on the statistical value, each SOC bin of the plurality of SOC bins including a subset of a range of SOC values;
calculating a deviation of each SOC value in the selected bin relative to a plurality of SOC values in the selected bin; and
determining whether the group of cells is healthy based on the deviation.

2. The system of claim 1, wherein the statistical value is an average group SOC calculated based on the measurements, and the deviation includes a group SOC deviation and a bin deviation, the group SOC deviation corresponding to a difference between the estimated SOC value and the average group SOC, the bin deviation corresponding to a difference between a SOC value in the selected bin and an average of the plurality of SOC values in the selected bin.

3. The system of claim 2, wherein determining whether the group of cells is healthy includes calculating a change in the deviation.

4. The system of claim 3, wherein the change in the deviation is based on a difference between the group SOC deviation and the bin deviation.

5. The system of claim 4, wherein the group of cells is determined to be healthy based on the change in the deviation being less than a threshold change value.

6. The system of claim 1, wherein each SOC value is acquired by calculating a voltage of the group of cells based on voltage samples taken during the selected time window, and estimating each SOC value based on an open circuit voltage (OCV)-SOC curve.

7. The system of claim 3, wherein the diagnostic module is configured to accumulate cell balancing commands from a cell balancing process.

8. The system of claim 7, wherein calculating the deviation includes compensating the change in the deviation based on the cell balancing commands.

9. The system of claim 1, wherein the battery assembly is at least one of a battery module and a battery pack of a vehicle.

10. A method of evaluating a battery assembly, comprising:
monitoring a group of cells of the battery assembly;
estimating a state of charge (SOC) value for the group of cells based on measurements performed during a selected time window;
calculating a statistical value related to the estimated SOC value for the group of cells;
assigning the estimated SOC value to a selected bin of a plurality of SOC bins based on the statistical value, each SOC bin of the plurality of SOC bins including a subset of a range of SOC values;
calculating a deviation of each SOC value in the selected bin relative to a plurality of SOC values in the selected bin; and
determining whether the group of cells is healthy based on the deviation.

11. The method of claim 10, wherein the statistical value is an average group SOC calculated based on the measurements, and the deviation includes a group SOC deviation and a bin deviation, the group SOC deviation corresponding to a difference between the estimated SOC value and the average group SOC, the bin deviation corresponding to a difference between a SOC value in the selected bin and an average of the plurality of SOC values in the selected bin.

12. The method of claim 11, wherein determining whether the group of cells is healthy includes calculating a change in the deviation.

13. The method of claim 12, wherein the change in the deviation is based on a difference between the group SOC deviation and the bin deviation.

14. The method of claim 13, wherein the group of cells is determined to be healthy based on the change in the deviation being less than a threshold change value.

15. The method of claim 12, wherein calculating the deviation includes compensating the deviation based on cell balancing commands accumulated from a cell balancing process.

16. The method of claim 10, wherein the battery assembly is at least one of a battery module and a battery pack of a vehicle.

17. A vehicle system comprising:
a memory having computer readable instructions; and
a processing device for executing the computer readable instructions, the computer readable instructions controlling the processing device to perform a method including:
monitoring a group of cells of a battery assembly;
estimating a state of charge (SOC) value for the group of cells based on measurements performed during a selected time window;
calculating a statistical value related to the estimated SOC value for the group of cells;
assigning the estimated SOC value to a selected bin of a plurality of SOC bins based on the statistical value, each SOC bin of the plurality of SOC bins including a subset of a range of SOC values;
calculating a deviation of each SOC value in the selected bin relative to a plurality of SOC values in the selected bin; and
determining whether the group of cells is healthy based on the deviation.

18. The vehicle system of claim 17, wherein the statistical value is an average group SOC calculated based on the measurements, and the deviation includes a group SOC deviation and a bin deviation, the group SOC deviation corresponding to a difference between the estimated SOC value and the average group SOC, the bin deviation corresponding to a difference between a SOC value in the selected bin and an average of the plurality of SOC values in the selected bin.

19. The vehicle system of claim 18, wherein determining whether the group of cells is healthy includes calculating a change in the deviation based on a difference between the group SOC deviation and the bin deviation.

20. The vehicle system of claim 17, wherein calculating the deviation includes compensating the deviation based on cell balancing commands accumulated from a cell balancing process.
